(19) United States
(12) Patent Application Publication
(10) Pub. No.: US 2008/0122657 A1
(43) Pub. Date: May 29, 2008

(54) Foot utility tool and a system and method for using the same

(76) Inventor: John S. Chen, Ridgewood, NJ (US)

Correspondence Address: SHEEHAN PHINNEY BASS & GREEN, PA;c/o PETER NIEVES, 1000 ELM STREET, MANCHESTER, NH, 03105-3701, US

(21) Appl. No.: 11/582,144

(22) Filed: Oct. 16, 2006

Related U.S. Application Data
(60) Provisional application No. 60/727,037, filed on Oct. 14, 2005.

(51) Int. Cl. H03K 17/94

(52) U.S. Cl. 341/20

(57) ABSTRACT

Footwear is provided for controlling a device via use of at least one foot. The footwear contains a first controller located internal to the footwear, the controller being capable of being activated by movement of a portion of the foot, wherein the first controller is capable of creating an activation signal upon being activated. The footwear also contains a transmitter capable of transmitting the activation signal. A device that is located separate from the footwear is capable of performing a predefined function after receiving the activation signal from the transmitter.

### CROSS-REFERENCE TO RELATED APPLICATION

This application claims priority to copending U.S. Provisional Application entitled, “FOOT UTILITY TOOL AND A SYSTEM AND METHOD FOR USING THE SAME,” having Ser. No. 60/727,037, filed Oct. 14, 2005, which is entirely incorporated herein by reference.

### FIELD OF THE INVENTION

The present invention is generally related to controllers, and more particularly is related to a device for translating foot motion into commands.

### BACKGROUND OF THE INVENTION

With advancement of technology, devices and machinery have become subject to many degrees of precision and control. To control devices and machinery, individuals typically utilize their hands and feet. As an example, hands may be used to control direction of a vehicle, while feet are used to control acceleration and deceleration.

Typically, foot control is provided by use of switches or other devices located external to the foot of an individual. Specifically, to provide foot control, an individual uses their foot to press against a switch or other control device that is located external to a shoe of the individual. Pressure on the switch or other control device is interpreted in accordance with a specific function associated with the switch. For this reason, foot control is limited in application.

With the ability to control additional functions of devices and machinery, additional ways of communicating such control through bodily functions becomes important. Control devices have been created that can be controlled through the use of portions of the body other than hands or feet. As an example, helmets have been created that are capable of controlling aiming of a camera or weapon in accordance with a sight of view of an individual using the helmet. While the creation of such control devices is advantageous, it would also be beneficial to take further advantage of foot control. Specifically, since the extent of foot control has been limited to the pressing of switches and controls located outside of the shoe of an individual, it would be beneficial to provide additional ways of control via use of the foot.

Thus, a heretofore unaddressed need exists in the industry to address the aforementioned deficiencies and inadequacies.

### SUMMARY OF THE INVENTION

Embodiments of the present invention provide a system and method for translating foot motions into commands. Briefly described, in architecture, one embodiment of the system, among others, can be implemented as follows. The system is footwear for controlling a device via use of at least one foot. The footwear contains a first controller located internal to the footwear, the controller being capable of being activated by movement of a portion of the foot, wherein the first controller is capable of creating an activation signal upon being activated. The footwear also contains a transmitter capable of transmitting the activation signal. A device that is located separate from the footwear is capable of performing a predefined function after receiving the activation signal from the transmitter.

Different embodiments of the invention provide for an additional controller for detecting motion, location, and position. In addition, the first controller may be located external to the footwear, but connected to the footwear.

Other systems, methods, features, and advantages of the present invention will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a cross sectional diagram of footwear containing a foot utility tool, in accordance with a first exemplary embodiment of the invention.

FIG. 2 is a schematic diagram of footwear containing a foot utility tool in accordance with a second exemplary embodiment of the invention.

FIG. 3 is a schematic diagram illustrating an example of footwear, with a foot utility tool, having an external controller that is located on an external portion of footwear.

FIG. 4 is a schematic diagram providing an example of footwear having a second controller thereon, which is in communication with a gyroscopic detection sensor.

FIG. 5 is a schematic diagram illustrating an embodiment of the footwear having both a controller for selecting and a second controller therein.

### DETAILED DESCRIPTION OF THE INVENTION

A Foot Utility Tool (FUT) is provided, which is a set of technologies, whereby an operator can initiate and sustain control function over devices by using their feet. The FUT technology contains several sub-components operated by feet. These sub-components may be used individually or in combinations to form larger permutations and matrixes. Use of these combinations is described in further detail herein.

The FUT provides control capability through selection (e.g., clicking) and through motion performed by a foot of a user. It should also be noted that the FUT may provide control capability through the combination of selection and one or more of motion, location, and/or position, as described herein. Features of control provided by the abovementioned are described in detail herein.

### Selection

As mentioned above, the FUT provides the capability of control through, among other features, selection. As an example, the selection feature may be compared to clicking a mouse connected to a computer. The selection feature may be provided by use of one of multiple different technologies. Technology associated with the selection feature may either include foot control provided through an individual using their foot to operate controls located within footwear, or foot control provided through an individual using their foot to operate controls that respond to actions taken on the exterior, or shell, of the footwear.

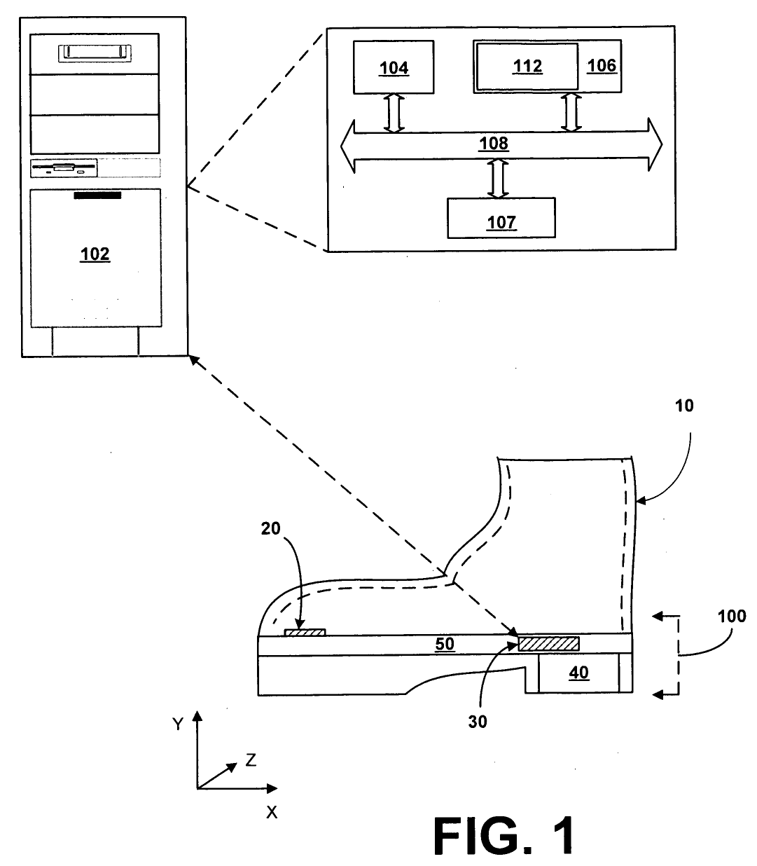

FIG. 1 is a cross sectional diagram of footwear 10 containing a FUT 100 in accordance with a first exemplary embodiment of the invention. As shown by FIG. 1, the FUT 100 contains an internal controller 20, a transmitter 30, and a power source 40. In accordance with the first exemplary embodiment of the invention, for ease of use and implementation, the internal controller 20, and transmitter 30 are positioned on a removable sole 50 of the footwear 10. It should be noted that in accordance with an alternative embodiment of the invention, the sole 50 may not be removable. In addition, location of the transmitter 30 may be separate from the sole 50, or the power source 40 may be a portion of the sole 50. Specifically, there are many different configurations for placement of the internal controller 20, transmitter 30, and power source 40, that are intended to be covered by the present invention, which all provide the capability of providing selection with the foot of an individual.

The controller 20 may be one of many different known controllers that serve as switches. As an example, the internal controller 20 may be a touch sensitive device or any pressure sensitive device that is capable of being activated when touched by the toe, or toes, of a user. In addition, to prevent accidental activation of the internal controller 20, it may be beneficial to have activation of the internal controller 20 require more than one touch of the internal controller 20. Further, the internal controller 20 may be sized and shaped so that curling of a toe of the individual using the footwear causes activation of the internal controller 20. It should be noted that the internal controller 20 may alternatively be activated by movement of a toe or toes to the left or right. As a result, activation of the internal controller 20 may be performed by motion in the X, Y, and/or Z-axis. Combination movement(s) such as curling the toe(s) then pressing to one side may also be used to activate the internal controller 20. These movement(s) may be used individually or combined. One or both feet of an individual may also be used to create multiple functions.

The controller 20 may also be a proximity sensor that is capable of being activated when the controller 20 is within a specific distance of an object such as, but not limited to, a wall or other surface, a second controller, or a detector. Having the controller 20 in the form of a proximity sensor provides the advantage of having the controller 20 activated when an individual wearing the footwear enters within a predefined distance of a detector. An example of a proximity sensor includes, but in not limited to, a magnetic proximity switch.

The internal controller 20 is capable of providing an activation signal when activated. The activation signal is received by the transmitter 30 by one of many known signal transmission methods. As an example, the internal controller 20 and transmitter 30 may have a wired connection so that the transmitter 30 is capable of receiving the activation signal and, thereafter, transmitting the activation signal to a destination. It should be noted that in accordance with an alternative embodiment of the invention, the internal controller 20 may have a transmitter 30 incorporated therein.

The transmitter 30 may be one of many known transmitters. Specifically, the transmitter 30 receives an activation signal and transmits the activation signal to a destination. In accordance with the present invention, the destination of the activation signal transmitted by the transmitter 30 is a computer 102 having a receiver (not shown). Receipt of the activation signal by the computer 102 may result in initiation of an event or a sequence of events defined by the computer 102.

As mentioned above, the events performed as a result of receipt of the activation signal can be provided for by software (e.g., firmware), hardware, or a combination thereof. In the currently contemplated best mode, the functions are specified in software, as an executable program, and are executed by a special or general-purpose digital computer, such as a personal computer (PC; IBM-compatible, Apple-compatible, or otherwise), workstation, minicomputer, or mainframe computer.

Generally, in terms of hardware architecture, the computer 102 may include a processor 104, memory 106, and one or more input and/or output (I/O) devices (or peripherals) 107 that are communicatively coupled via a local interface 110. The local interface 110 can be, for example but not limited to, one or more buses or other wired or wireless connections, as is known in the art. The local interface 110 may have additional elements, which are omitted for simplicity, such as controllers, buffers (caches), drivers, repeaters, and receivers, to enable communications. Further, the local interface 110 may include address, control, and/or data connections to enable appropriate communications among the aforementioned components.

When the computer 102 is in operation, the processor 104 is configured to execute software 112 stored within the memory 106, to communicate data to and from the memory 106, and to generally control operations of the computer 102 pursuant to the software 112. Specifically, the memory 106 has software 112 stored therein that defines an event or a sequence of events that are to be performed upon receipt of the activation signal. As a result, the computer 102 may use the activation signal to actuate mechanical, electrical, pneumatic, hydraulic, optical, magnetic, and/or other types of devices.

It should be noted that the activation signal may instead be received by a device other than a computer, such as, but not limited to, a microcontroller, where the device is capable of associating a function to be executed with receipt of the activation signal.

Since one having ordinary skill in the art would understand the process of a computer performing an event, as defined by software, in response to receipt of an activation signal, further description of the process is not provided herein.

The power source 40 of FIG. 1 is shown as being located within a heel 42 of the footwear 10. It should be noted, however, that the power source 40 may be located in a different portion of the footwear 10. As mentioned above, the power source 40 may be located within the sole 50 of the footwear 10. Alternatively, the power source 40 may be located in a different portion of the footwear 10, such as, but not limited to, a tongue of the footwear 10, or any other location. The power source 40 may also be one of many different categories of power source 40. For example, the power source 40 may be in the form of removable batteries or stationary rechargeable batteries.

It should be noted that the footwear 10 may be one of many known categories of footwear. As an example, the footwear 10 may be a shoe, boot, sandal, or slipper. In fact, one having ordinary skill in the art could even provide the FUT 100 within a sock (not shown).

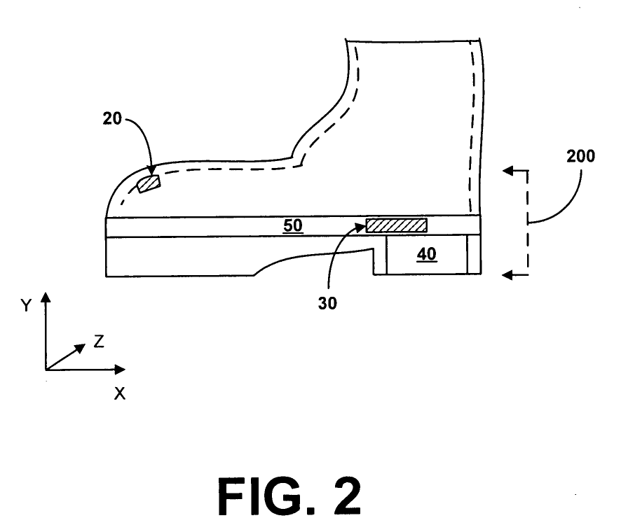

FIG. 2 is a schematic diagram illustrating a FUT 200 in accordance with a second exemplary embodiment of the invention. As shown by FIG. 2, the FUT 200 of the second exemplary embodiment of the invention has the internal controller 20 located on a top inner portion of the footwear 10. In this embodiment activation of the FUT 200 is provided by the individual lifting his/her toe(s) upward to contact the internal controller 20 located on the top inner portion of the footwear 10. As mentioned above with regard to the first exemplary embodiment of the invention, activation of the internal controller 20 may also be provided by the individual moving his/her toe(s) upward and to the left or right.

It should be noted that while the first and second exemplary embodiments of the invention provide for activation of an internal controller by a toe or toes on an individual wearing the footwear, the internal controller may instead be located in a different location within the inner portion of the footwear.

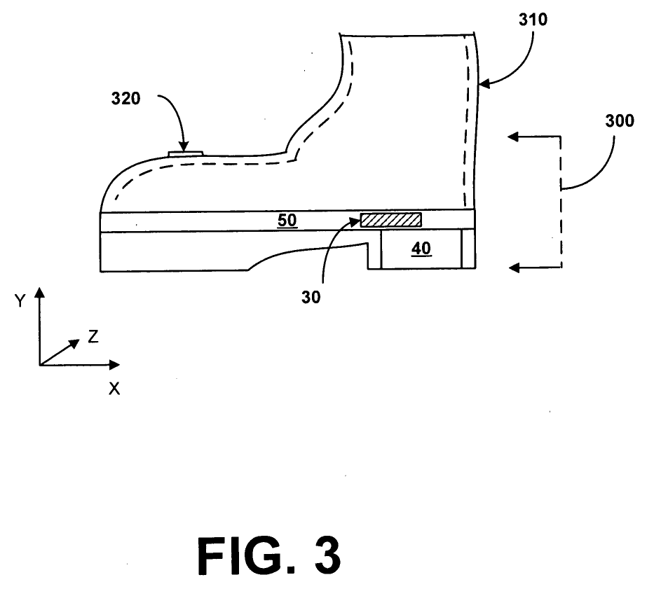

In accordance with a third exemplary embodiment of the invention, an external controller may be located on an exterior portion of the footwear. As an example, a touch sensitive device, or pressure sensitive device, may be provided on an exterior portion of the footwear, which is capable of being activated by pressing on the exterior controller. FIG. 3 is a schematic diagram illustrating an example of footwear 310, with a FUT 300, having an external controller 320 that is located on an external portion of footwear 310. It should be noted that the transmitter 30 and power source 40 may still be located internal to the footwear 310 or may also be located external to the footwear 310, or a side portion of the footwear 310.

By having the external controller 320 located on an external portion of the footwear 310, the external controller 320 may be activated by pressing the footwear 310 against a surface such as, but not limited to, a wall, a desk, or footwear located on a second foot of an individual. It should be noted that location of the external controller 320 may be on a top portion of the footwear 310 or on a bottom portion of the footwear 310, or on a side portion of the footwear 310.

The external controller 320 may take one of many different alternative forms. As a first example, the external controller 320 may encompass most of, or the entire, external portion of the footwear 310 so that touching any external portion of the footwear 310 will result in activation of the external controller 320. As an example, a top external portion of the footwear 310 may be entirely constructed of a touch sensitive, pressure sensitive shell, or optical shell. As a result, touching of any portion of the top external portion of the footwear 310 would result in activation of the external controller 320.

In accordance with a fourth exemplary embodiment of the invention, footwear may contain both internal and external controllers so as to provide for multiple functions by the same footwear located on one foot.

### Motion, Location, and/or Position

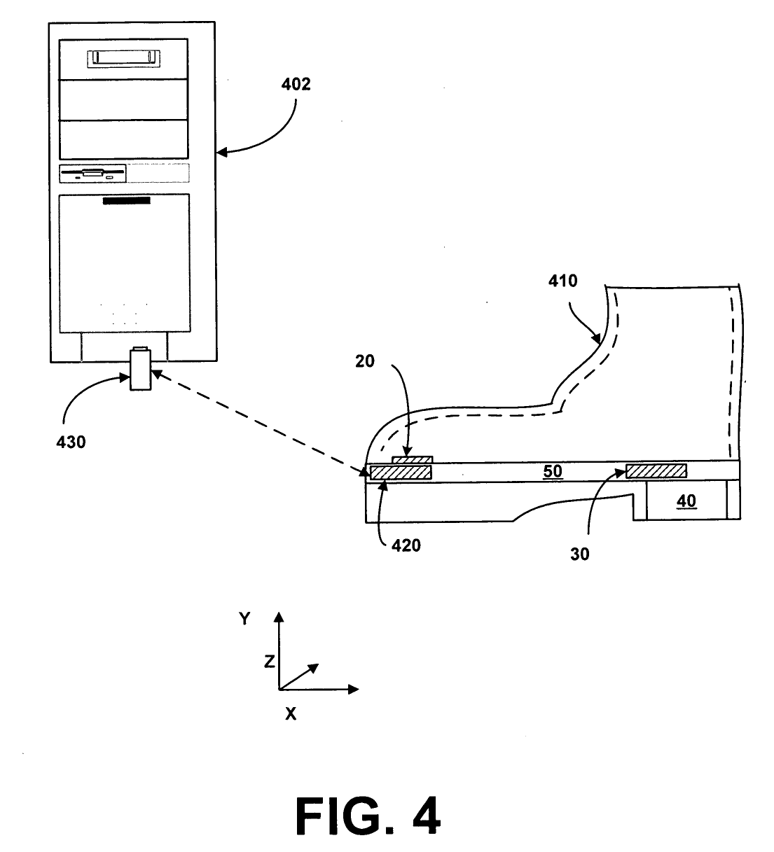

In accordance with the present invention, in addition, or instead of, the internal 20 or external 320 controller, the footwear 410 (FIG. 4) may also contain a second controller 420 (FIG. 4) that is capable of responding to motion, location, and/or position. Motion, location, and/or position as detected by the second controller 420 (FIG. 4) is in the X, Y, and Z-axis, where a specific motion, location, and/or position results in actuation of a specific function, examples of which are provided herein for exemplary purposes.

Position of footwear in the X, Y, and Z-axis may be determined by using a second controller 420 (FIG. 4) such as, but not limited to, a gyroscopic device that uses the Coriolis effect of the gyroscopic device to sense direction of movement and speed of movement. As is known by those having ordinary skill in the art, a gyroscopic device works by determining motion, location, and/or position of the gyroscopic device in comparison to a stationary gyroscopic detection sensor. Specifically, in accordance with the present invention, the gyroscopic device may be located on a portion of the footwear, while the gyroscopic detection sensor may be located at a separate location, such as, but not limited to, connected to the universal serial bus port of a computer 402. FIG. 4 is a schematic diagram providing an example of footwear 410 having the second controller 420 thereon, which is in communication with a gyroscopic detection sensor 430.

Alternatively, radio frequency triangulation may be used to determine motion, location, and/or position of the footwear. As an example, a radio frequency transmitter may be located on the footwear 410 as the second controller 420, where a separate detection sensor 430 determines motion, location, and/or position of the radio frequency transmitter by receiving and analyzing received radio frequency signals received from the radio frequency transmitter. It should be noted that the separate detection sensor may be located in one of many different locations. As an example, the sensor 430 may be connected to the computer 402, attached to a belt of the user (or any other body part of the user), or even attached to a second piece of footwear worn by the user. In a situation where the second controller 420 is worn on a first piece of footwear 410 and the sensor 430 is worn on a second piece of footwear, motion, location, and/or position of the first piece of footwear would be provided in comparison to the second piece of footwear. Such motion, location, and/or position of the first piece of footwear can then be transmitted from the sensor 430 to the computer 402 for interpretation in accordance with software therein.

Position and motion of footwear in the X, Y, and Z-axis may also be provided by a mechanical “mouse” or ball device incorporated into the base of the footwear capable of sensing movement and/or location. Another example would be where there is an optical sensor placed on the footwear capable of sensing location and movement. A further example would be the use of an electrical field to measure location and/or movement in relation to the other foot and/or exterior reference point(s). The location of the sensor(s) can then be both internal and external of the footwear and may be in multiple exterior locations. These movement(s) may be used individually or combined, and may be used by one or both feet to create single or multiple functions.

It should be noted that the second controller 420 may be located in many different portions of the footwear 410. FIG. 4 shows the second controller 420 as being located on the sole 50 of the footwear 410.

Use of the second controller 420 provides multiple functions. As an example, through use of the second controller 420 an individual wearing the footwear 410 can use their foot to write letters of the alphabet, control a cursor on a computer monitor, or perform one of many other functions as defined by software.

In addition to the abovementioned, the footwear may use the combination of a controller for selecting, such as the internal or external controller, and the second controller 420. As an example, the user may use the selection feature of the internal controller 20 to allow reading of the second controller 420. The combination of the selection feature and the second controller 420 prevents constant detection of motion, location, and/or position, but instead, only allows such detection at a time of selection as provided by an internal controller or an external controller.

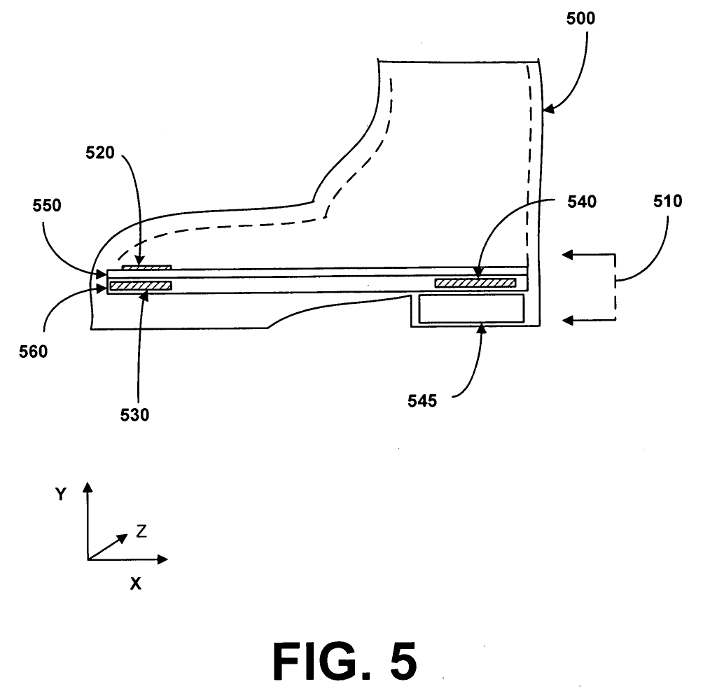

FIG. 5 is a schematic diagram illustrating an embodiment of footwear 500, having a FUT 510. The footwear 500 contains 2 soles, namely, a first sole 550 and a second sole 560. The first sole 550 has an internal controller 520 thereon, as described herein. Beneath the first sole 550, the second sole 560 has a second controller 530 for detection of motion, location, and/or position, and a transmitter 540 for transmitting activation signals derived from the internal controller 520. Within the heel of the footwear 500 is a power source 545.

The sub-components of the footwear 500 of FIG. 5 can be broken down into three major categories: 1) a technique that involves using the toe(s) of a person's foot/feet to operate controls located inside footwear; 2) a technique that incorporates controls that respond to action(s) on the exterior, or shell, of the footwear; and 3) a technique where the motion, location, and/or position of the footwear will cause the control function(s). These controls 1, 2, 3, may be used individually or linked together to form larger command sets.

The commands generated by 1, 2, and 3 can be sent via wired or wireless communication to a central controller, to be organized into complex command(s).

A control signal(s) generated from area 1, 2, and 3, sent either individually or in various combinations, can then be processed logically by computers, via use of software, and/or micro-controllers, to perform specific functionality.

By using these abovementioned singly or in combination, a single control command, or a large number of control commands, can be generated. As a result, a person using only their feet can control myriads of other tools, equipment, and devices.

It should be emphasized that the above-described embodiments of the present invention are merely possible examples of implementations, merely set forth for a clear understanding of the principles of the invention. Many variations and modifications may be made to the above-described embodiments of the invention without departing substantially from the spirit and principles of the invention. All such modifications and variations are intended to be included herein within the scope of this disclosure and the present invention and protected by the following claims.

What is claimed is:

1. A system for controlling a device via use of at least one foot, said system comprising:
footwear further comprising:
a first controller located internal to said footwear, said controller being capable of being activated by movement of a portion of said foot, wherein said first controller is capable of creating an activation signal upon being activated;
a transmitter capable of transmitting said activation signal; and
a device located separate from said footwear, said device being capable of performing a predefined function after receiving said activation signal from said transmitter.

2. The system of claim 1, wherein said first controller is located on a top portion of a sole located within said footwear, and wherein said first controller is capable of being activated via at least one toe of a foot.

3. The system of claim 1, wherein said first controller is located on a top inner portion of said footwear, above a foot located within said footwear, and wherein said first controller is capable of being activated by lifting of a portion of said foot toward said top inner portion of said footwear.

4. The system of claim 1, wherein said device is a computer, said computer having a memory and a processor, wherein said processor is capable of performing steps as defined in software stored within said memory, wherein said predefined functions are defined by said software, and wherein said computer further comprises a receiver capable of receiving said activation signal.

5. The system of claim 1, further comprising a second controller, wherein said second controller is capable of detecting information selected from the group consisting of motion, location, and position, and reporting said information to said device.

6. The system of claim 5, said system being further defined by:
said second controller being a gyroscopic device;
said device being a computer, said computer having a memory and a processor, wherein said processor is capable of performing steps as defined in software stored within said memory, wherein said predefined functions are defined by said software, and wherein said computer further comprises a gyroscopic detection sensor capable of detecting motion, location, and position.

7. The system of claim 1, wherein said first controller is responsive to pressure.

8. The system of claim 1, wherein said footwear further comprises a power source

9. A foot utility tool for controlling a device via use of at least one foot, comprising:
footwear further comprising:
a first controller located external to said footwear, said controller being capable of being activated by movement of a portion of said foot, wherein said first controller is capable of creating an activation signal upon being activated;
a transmitter capable of transmitting said activation signal; and
a device located separate from said footwear, said device being capable of performing a predefined function after receiving said activation signal from said transmitter.

10. The system of claim 9, wherein said device is a computer, said computer having a memory and a processor, wherein said processor is capable of performing steps as defined in software stored within said memory, wherein said predefined functions are defined by said software, and wherein said computer further comprises a receiver capable of receiving said activation signal.

11. The system of claim 9, further comprising a second controller, wherein said second controller is capable of detecting information selected from the group consisting of motion, location, and position, and reporting said information to said device.

12. The system of claim 9, wherein said first controller is responsive to pressure.

13. Footwear capable of controlling a device via use of at least one foot, said footwear comprising:
a first controller located internal to said footwear, said controller being capable of being activated by movement of a portion of said foot, wherein said first controller is capable of creating an activation signal upon being activated; and
a transmitter capable of transmitting said activation signal.

14. The footwear of claim 13, wherein said first controller is located on a top inner portion of said footwear, above a foot located within said footwear, and wherein said first controller is capable of being activated by lifting of a portion of said foot toward said top inner portion of said footwear.

15. The footwear of claim 13, wherein said first controller is located on a top portion of a sole located within said footwear, and wherein said first controller is capable of being activated via at least one toe of a foot.

16. The footwear of claim 13, further comprising a second controller, wherein said second controller is capable of detecting information selected from the group consisting of motion, location, and position, and reporting said information to said device.

17. The footwear of claim 13, wherein said first controller is responsive to pressure.

18. The footwear of claim 13, further comprising a power source.

19. The footwear of claim 16, further comprising a first sole having said first controller thereon, and a second sole having said second controller and a transmitter thereon.

20. The footwear of claim 13, wherein said device is a computer.
